(19) United States
(12) Patent Application Publication
(10) Pub. No.: US 2009/0300910 A1
(43) Pub. Date: Dec. 10, 2009

(54) Method for Applying Electrical Conductor Patterns to a Target Component of Plastic

(76) Inventors: Markus Pfletschinger, Eningen (DE); Bernd Schwarz, Walddorfhaslach (DE); Jan Krüger, Stuttgart (DE); Ingmar Petersen, Esslingen (DE)

Correspondence Address: K.F. ROSS P.C., 5683 RIVERDALE AVENUE, SUITE 203 BOX 900, BRONX, NY, 10471-0900, US

(21) Appl. No.: 11/989,108

(22) PCT Filed: Apr. 10, 2006
(86) PCT No.: PCT/EP2006/003238

§ 371 Date: Jul. 16, 2009

(30) Foreign Application Priority Data
Jul. 21, 2005 (DE) 10 2005 034 082.2

(51) Int. Cl. H05K 3/20

(52) U.S. Cl. 29/831

(57) ABSTRACT

The invention relates to a method for applying electrical conductor patterns (1) to a target component (9) of plastic, it being provided according to the invention that a transfer medium on which the conductor patterns (1) are detachably arranged is placed in a mould part (3, 4) and the mould part (3, 4) is filled with a polymer material, the finished target component (9) being removed from the mould part (3, 4) after the filling.

The invention relates to a method of applying electric conductor structures to a plastic target component according to the characteristics of the introductory clause of claim 1.

### PRIOR ART

The production of target components made of plastic is known. It is known, for example with motor vehicles, to produce flat components, such as engine hoods, roofs, trunk lids, and the like from plastic for reasons of reducing weight. Mounted parts, such as fenders, doors, bumpers, and the like, of motor vehicles can be manufactured from plastic. In addition to reducing weight, these components made of plastic have the advantage over components of steel in that they cannot rust.

In such motor-vehicle components, it is further known to also integrate or apply electrically conductive structures (conductors) that carry energy or signals. To this end, currently known methods for applying the conductor structures are used, wherein initially the target component is produced so that it has its final shape. Subsequently, the conductor structures are applied, for example, by fastening on wires or stampings. However, this method of retrospectively applying the conductor structures has disadvantages, since a complex adjustment process between the material of the conductor structure and the target material is necessary, and the durability of the conductor structures required on the target component for the subsequent operation of the motor vehicle is not ensured. Furthermore, a complex installation process is required in a disadvantageous manner. In addition, large problems exist with the retrospective application of the conductor structures to the target component, since it is usually complex, such as curved, bent, or such. This results in the retrospective application of conductor structures, if it is possible at all, being very complex.

### DESCRIPTION OF THE INVENTION

The object of the invention is therefore to provide a method of applying electric conductor structures to a plastic target component, which is simple to do and which avoids the disadvantages described above. Furthermore, a target component having electric conductor structures produced according to the method is to be provided.

This object is attained by the characteristics of patent claim 1.

According to the invention a transfer medium, on which the conductor structures are mounted in a detachable manner, is introduced into a mold part (also called a mold), and the mold part is then filled with a plastic material, and after the filling process the finished target component is removed from the mold part. This method has the advantage that initially the conductor structures are applied to a transfer medium, and in a particular embodiment of the invention the transfer medium is a film made of plastic. The use of a transfer medium further has the advantage that it only has to have dimensions corresponding to the area of the conductor structure. As a result, it is much easier to manage. Furthermore, the advantage exists that the material of the transfer medium and the material of the conductor structures can be coordinated in such a manner that they adhere to each other at least during manufacture of the target component, possibly after manufacture of the target component, however, so that stripping of the transfer medium is also possible. Another advantage is that the transfer medium with the conductors thereon does not have to have the final shape of the target component, since this shape can be imparted after insertion into the mold part and after the subsequent filling of the mold part with plastic material. This supports design freedom for the target component and its rational fabrication in an advantageous manner. Particularly in case the transfer medium is removed after manufacture of the target component the method according to the invention provides the advantage that the conductor structures are then surrounded by the plastic material on their surfaces facing away from the transfer medium, and are thereby permanently and firmly bedded in the target component so that they can no longer separate from the target component during its subsequent use. With the transfer medium stripped off, the additional advantage is provided that a smooth surface of the target component has been created which no longer needs to be processed, especially with a later painting, and that the conductor structures no longer project past the outer surface of the target component. Additionally, this substantially facilitates the application of a carrier or retaining component (such as a frame) of additional modules (such as electronic modules), or contacts.

In a further development of the invention the plastic material is a heated plastic melt that is injected into the mold part until the mold part, including the introduced transfer medium, is filled with the conductor structures, or that a foaming plastic material is injected as the plastic material into the mold part in such an amount that it foams after introduction and thereby fills the cavity of the mold part, including the introduced transfer medium with the conductor structures. It should be noted at this point that a PUR foam is excluded as the foaming plastic material, however all other plastic materials that foam are included.

Overall either the introduction of a heated plastic melt or of the foaming plastic material offers great freedom with regard to the design and production costs of the target component on one hand, but the plastic material can also be selected depending on the end use of the target component on the other hand. Foaming plastic materials, for example, are preferred, if a savings of weight at the installation site of the target component is important, while target components that are made from a heated plastic melt are more stable due to the greater density of the finished target component.

A further development of the invention provides that the transfer medium is reshaped before or during the filling process. Since before the transfer medium is introduced into the mold part, its shape can deviate but does not necessarily do so, it is of advantage to reshape the transfer medium before or during the filling process, i.e. to conform it to the inside shape of the mold part that corresponds to the outside shape of the finished target component. This can be carried out, for example, mechanically, using vacuum, with the aid of an electrostatic charge in the mold part, or similar. The important part during the introduction of the transfer medium into the mold part, regardless of whether the transfer medium is reshaped before or during the filling process, or maintains its original shape, is that the transfer medium be fixed in the mold part such that after the production of the target component the transfer medium is on its outside surface, i.e. forms its outside surface at least partially, or even completely.

A further development of the invention provides that the entire target component is reshaped during or after the filling process. This means that the target component obtains its final shape from the shape of the mold part, or that the target component obtains its initial shape by filling the mold part with the plastic material. After removing the finished target component from the mold it is then plastically reshaped by a suitable method. Particularly, it is given its final shape by the effect of heat and pressure. To this end attention must be paid to the fact that the conductor structures are not damaged with this subsequent reshaping, in particular, that breaks are avoided.

In a further development of the invention the transfer medium is a film, which has the particular advantage that the conductor structures can be applied upon it in a simple, quick, and cost-effective manner, and which provides adequate flexibility during its introduction into the mold part.

A further development of the invention is that the transfer medium remains on the target component as a protective layer after its manufacture, is partially removed (the remaining part provides a protective layer, while the conductor structures are exposed in the edge of the transfer medium for further processing, particularly for contacts), or is completely removed. The partial or complete removal of the transfer medium provides the possibility that the conductor structures are then exposed, and are available for further processing. The further processing can be an electric connection with electric or electronic components that are mounted on the target component in order to form an electronic device at that location, such as an antenna amplifier of a motor vehicle. Additionally or alternatively the conductor structures may also be simple electric connections for power supply or signal transfer, and may have a plug connector at their ends. A target component can thus be produced in a preferred embodiment of the invention with conductor structures carried thereupon, on which electric, electronic, and connecting components are subsequently provided that form an electronic device.

In a further development of the invention the transfer medium is a fiber composite, particularly the transfer medium is paper. Paper is extremely inexpensive, and is supplied on a roll. It is also easy to imprint. Waxed paper can be particularly suited for the transfer. Fabric is another very tear-resistant fiber composite. In addition, other fiber composites are also possible.

In a further development of the invention the transfer medium is an integral part of the mold part. In this embodiment the conductor structures are applied to the inside surface of the mold part by suitable methods, the connection between the conductor structures and the mold part being chosen such that after filling of the mold part with the plastic material and removal of the mold part, the conductor structures remain on the finished target component, and thus is separated from the mold part.

In a further development of the invention the target component is produced according to the method according to the invention, the target component being characterized by its use as an integral part of a motor vehicle, particularly a fender, a motor-vehicle roof, a hatchback, a bumper, a motor-vehicle window, or also, for example, a housing of an electronic device that is integrated in the motor vehicle. This means that the plastic material for the production of the target component is translucent, or transparent. Furthermore, the plastic material may already be color-tinted according to the installation site, or subsequently equipped with color-tinted paint.

### BRIEF DESCRIPTION OF THE DRAWING

Embodiments of the invention, which the invention is however not limited to, are described in detail below with reference to the figures. Therein:

FIG. 1 shows electric conductor structures applied to a transfer medium,

FIG. 2 shows a mold for receiving the transfer medium,

FIG. 3 shows the closed mold after the introduction of the foaming plastic material,

FIG. 4 is a section through the finished target component,

FIG. 5 shows the target component before and after stripping off the transfer medium,

FIG. 6 illustrates another embodiment of a mold, and the introduction of the (here, not foaming) plastic material.

### WAYS FOR CARRYING OUT THE INVENTION

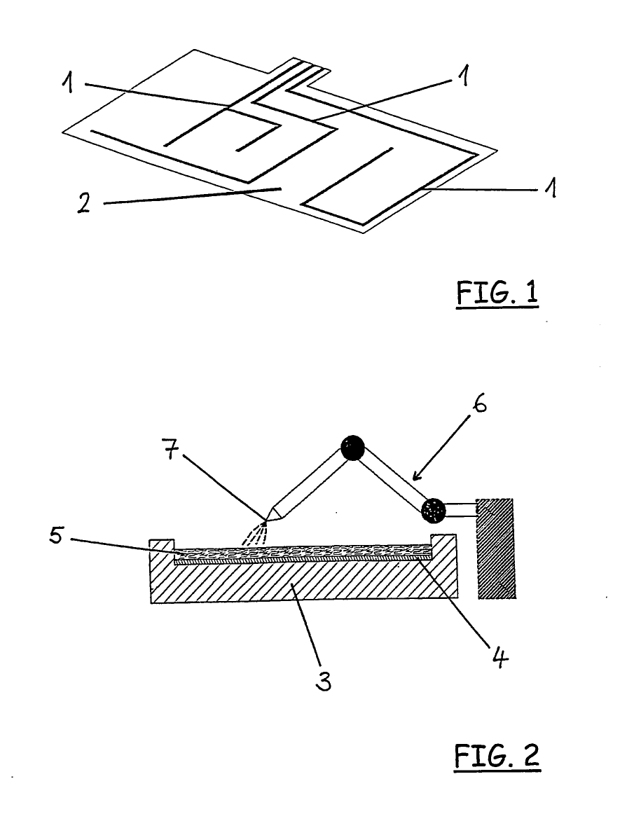

FIG. 1 illustrates conductor structures 1 that are applied to a transfer medium, particularly to a thin film 2.

Pastes, such as silver polymer pastes, CU-pastes (copper), or such, can be used as the conductor structures. PET, PMMA, and plastic films in general can be used as the films, since they do not form a good bond with the target component. The application of the conductor structures to the film may be carried out by screen printing, pad printing, and all current printing methods also used with paint (spraying and sputtering). To this end, the above list meant to be exemplary, not limitative.

Such a film 2 illustrated in FIG. 1 with a conductor structure 1 applied thereupon either already has the final shape of the subsequent finished target component, or can be brought to its final shape before or during the production of the target component, or after its production.

FIG. 2 shows a mold for receiving the transfer medium. The mold is usually comprised of two or more parts in order to make it possible to introduce the transfer medium into the mold. In this embodiment a first mold part 3 is provided into which a coat of paint, particularly a paint film 4, is introduced. This coat of paint can be present, but does not necessarily have to be. After introducing the coat of paint, or if it is not present, a foaming plastic (foam layer 5, not a PUR foam, but instead all other foaming plastic materials) is introduced for the first time into the first mold part 3 by an applicator 6. To this end, the foaming plastic material is introduced into the first mold part 3 in a plane or different manner by the nozzle 7 of the applicator 6. The foaming plastic material must be matched to the paint film 4 with regard to compatibility and expansion coefficient. The expansion coefficient of paint film 4 and foam should be adjusted to each other exactly so that no bimetal separation effect will occur.

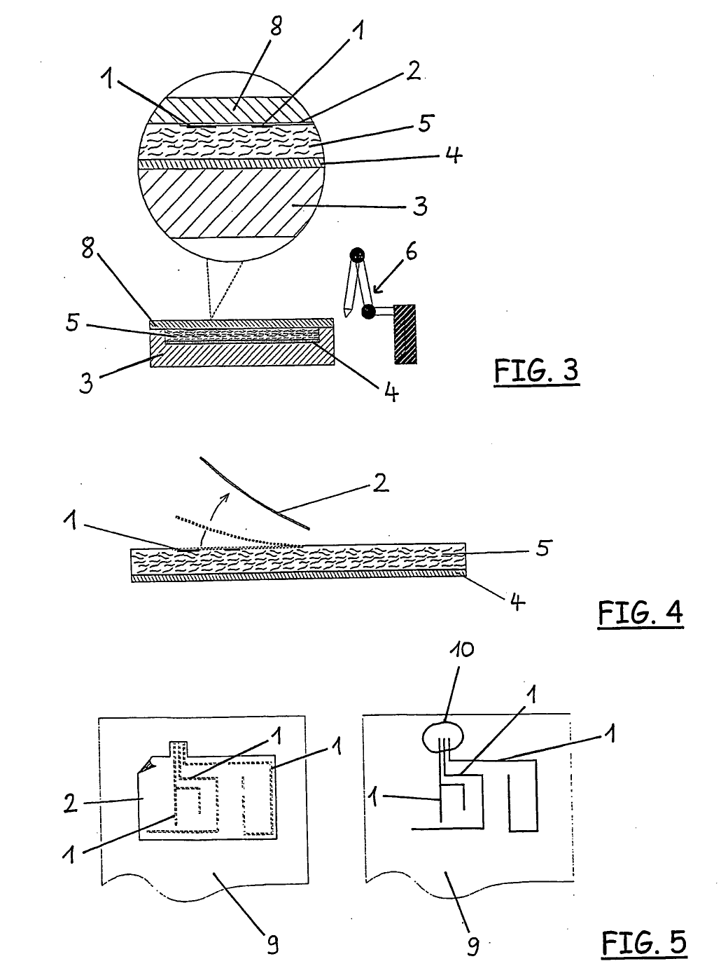

FIG. 3 shows the closed mold after introduction of the foaming plastic material. After the foaming plastic material has been introduced into the first mold part 3, the mold is closed, in this case by at least one additional mold part 8. Before closing, the transfer medium (film 2 with applied conductor structures 1 according to FIG. 1) is introduced into the mold too, to which end it is, for example, placed on the foam layer 5, or adhered in the cavity of the additional mold part 8. In an alternative embodiment the transfer medium may also be formed by the additional mold part 8, which in this case carries the conductor structures 1. After the forming tool has been closed, the foam layer 5 begins to swell, resulting in heat and pressure being generated such that either the conductor structure 1 is pressed by the foam to the film 2, or the conductor structure 1 is foamed to the mold part 8. In this process the amount of the filled-in plastic material is selected such that the entire cavity of the mold, including the introduced conductor structures (and possibly the introduced film 2) is completely filled during the foaming process. In case a larger amount is selected, it may be necessary to provide a vent in the mold.

FIG. 4 shows a section of the finished target component, showing that the conductor structures 1 permanently adhering to the foam layer is separated from the transfer medium (in this case film 2, alternatively, for example, mold part 8). In this manner the conductor structures 1 are exposed at least partially, and can be subjected to further processing, particularly painting or attaching of electric, electronic, and like components.

FIG. 5 shows the target component before and after the removal of the transfer medium. Here, a finished target component 9 is shown that has been provided with the constructor structures 1 in a limited part of its area, as described above. If it is assumed that the film 2 is utilized as the transfer medium, it still adheres to the target component 9 after its removal from the mold. This is of advantage, if, for example, the target component 9 is manufactured at a motor-vehicle manufacturer's supplier's plant, and is supplied to a motor-vehicle manufacturer for final assembly. In this case the film 2 offers protection to the conductor structures 1, particularly from corrosion or oxidation, as well as mechanical protection. This also applies in case the target component 9 was manufactured, but must first be stored before further processing, particularly with contact of the conductor structures 1 with additional electronic components. In this case the temporary film 2 on the target component 9 also provides protection of the conductor structures 1 present on it. This is illustrated on the left in FIG. 5, while the right in FIG. 5 shows that the film 2 has been removed completely (partial removal also being possible). Thus, the conductor structures 1 are exposed on the surface of the target component 9, where it should be noted that the surface of the target component 9 and the surface of the conductor structures 1 present thereon are flush with each other so that the conductor structures 1 do not protrude from the surface of the target component 9, or are imbedded underneath it.

It should be noted at this point that after removal of the target component 9 it has its final shape, or can still be trimmed. In this case it is advantageous that it be processed such that a contact area 10 is created at the ends of the individual conductors 1.

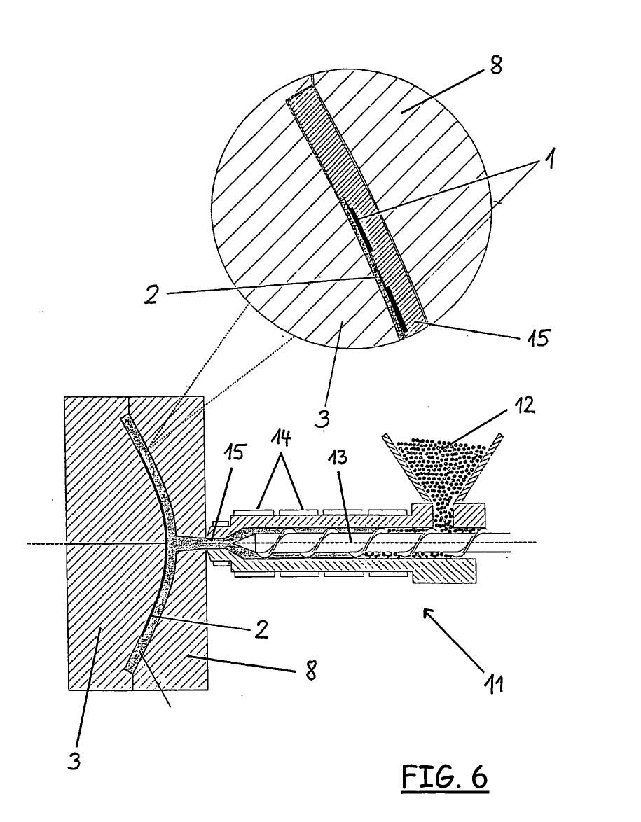

FIG. 6 shows an additional embodiment of a mold and the introduction of the (here not foaming) plastic material for the production of a target component. After the transfer medium has been provided with the conductor structures according to FIG. 1, it is introduced into a mold, which in this embodiment also consists of the first mold part 3 and at least the additional mold part 8. This mold is an integral part of, or connected to a generally known extruder 11, the moldable plastic material being fed to the mold via a worm 13 in the form of granulate 12. To this end the granulate 12 is heated via a heater 14 as it is fed so that at the end of the extruder device 11 a heated plastic melt 15 can be injected into the mold via a corresponding feed opening of it. The plastic melt 15 fills the cavity of the mold part 3, 8 and simultaneously also surrounds the transfer medium, and if the conductor structures 1 are directed toward the inside also beds the conductor structures 1. This situation is illustrated in the detailed view of FIG. 6. At this point it should be mentioned that the film 2 with the conductor structures 1 carried thereon or therein does not necessarily have to be on the surface of one of the mold parts 3, 8, but may also be in the cavity formed by the mold parts 3, 8 such that it is surrounded at least partially, particularly completely, by the plastic melt 15. After curing of the heated plastic melt 15 the target component (see FIG. 5) can then be removed from the mold, and subjected to further processing (particularly, the removal of the transfer medium will occur, which will no longer be needed).

### LIST OF REFERENCE SYMBOLS

1 conductor structures
2 film
3 first mold part
4 paint film
5 PUR layer
6 applicator
7 nozzle
8 additional mold part
9 target component
10 contacting area
11 extruder device
12 granulate
13 worm screw
14 heating means
15 heated plastic melt

1. A method of applying electric conductor structures to a plastic target component, the method comprising the steps of:
introducing a transfer medium on which the conductor structures are detachably mounted into a cavity of a mold part;
filling the cavity of mold part with a plastic material, and
thereafter removing the finished target component from the cavity of the mold part.

2. The method according to claim 1 wherein a heated plastic melt is filled into the mold part as the plastic material.

3. The method according to claim 1 wherein a foaming plastic material that is not a polyurethane foam is filled into the mold part as the plastic material.

4. The method according to claim 1 wherein the transfer medium is reshaped to conform to an inner surface of the mold part before or during the filling process.

5. The method according to claim 1 wherein the target component is reshaped during or after the filling process to conform to an outside surface of the finished component.

6. The method according to claim 1 wherein the transfer medium is a film.

7. The method according to claim 1 wherein the transfer medium is not partially or completely removed after completion of the target component.

8. The method according to claim 1 wherein the transfer medium is a fiber composite, particularly paper.

9. The method according to claim 1 wherein the transfer medium is an integral part of the mold part.

10. A target component produced according to the method according to claim 1.

11. The target component according to claim 10, used as an integral part of a motor vehicle.

12. The target component according to claim 11 wherein the integral part of the motor vehicle is a fender, a motor-vehicle roof, a hatchback, a bumper, a motor-vehicle window, or a housing of an electronic device that is installed in the motor vehicle.

13. A method of making a three-dimensional molded motor-vehicle component, the method comprising the steps of sequentially:
applying an array of conductors to a flexible film such that the conductors can be separated from the film without damage to the conductors or to the film;
inserting the flexible film with the applied array of conductors into a cavity of a mold with the film against an inside surface of the mold and the conductors turned inward;
filling the mold with molten plastic under pressure and thereby pressing the film against the inside surface such that it conforms to the shape thereof and the plastic imbeds the conductors;
hardening the plastic;
removing the hardened plastic from the cavity with the conductors imbedded in its outer surface and the film flush with its outer surface; and
stripping the film off the hardened plastic and exposing the conductors.

14. The method defined in claim 13 wherein the plastic is put under pressure by using a foaming plastic.

15. The method defined in claim 13 wherein the plastic is put under pressure by injecting it under pressure into the cavity.

16. The method defined in claim 13 wherein the conductors are flat conductive traces that are flush with the outside surface of the body after stripping of the film.
